(19) United States
(12) Patent Application Publication
(10) Pub. No.: US 2026/0368584 A1
(43) Pub. Date: Nov. 19, 2026

(54) ROUTING SIGNALS BY CIRCUITRY

(71) Applicant: IQM FINLAND OY, Espoo (FI)

(72) Inventor: Kristinn JULIUSSON, Espoo (FI)

(21) Appl. No.: 19/480,250

(22) PCT Filed: Apr. 29, 2024
(86) PCT No.: PCT/FI2024/050202

§ 371 Date: Oct. 30, 2025

(30) Foreign Application Priority Data
May 3, 2023 (FI) 20235491

(51) Int. Cl. G06N 10/20; G06N 10/40; H10N 60/12

(52) U.S. Cl. CPC G06N 10/20; G06N 10/40; H10N 60/12

(57) ABSTRACT

There is provided circuitry for routing input signals, comprising a transmission line for receiving an input signal, at least one control line for carrying a control current, and switching circuitries each of which comprises a resonator configured to couple to the transmission line based on at least one of an inductive coupling and a capacitive coupling, and provide an output, and a superconducting element comprising a quantum device configured to couple to the resonator based on at least one of an inductive coupling and a capacitive coupling, wherein the quantum devices of the switching circuitries comprise resonance frequencies that have different periodicities in response to levels of the control current for selectively controlling propagation of the input signal to outputs of resonators of the switching circuitries.

### TECHNICAL FIELD

The invention relates to a circuitry for routing signals received by a transmission line.

### BACKGROUND

A basic functional unit of quantum computing is the qubit, in the following also referred to as a quantum device, of which there may be a large number on a quantum processing unit. Throughout this description, the term quantum processing unit and its acronym QPU refer to a piece of hardware in which a plurality of circuit elements, at least some of which are suitable and designed for quantum computing, exist in a physical form suitable for being operated in the cryogenically cooled environment that is required for quantum computing. The term quantum circuit refers to a configurable abstraction of quantum gates performed during quantum computation. The term quantum computing system refers to a larger entity that comprises one or more QPUs, the control arrangement located outside the cryogenically cooled environment, and the signal paths between the two.

Each qubit used for a quantum computation can assume a superposition of two basis states. For concise reference, the superposition is often referred to as the quantum state, or simply just state, of the qubit. In general, a multi-qubit system can be in a superposition of multi-qubit eigenstates.

In order to obtain a useful result of a quantum computation, a readout operation must be performed. The readout operation causes the quantum state of a single qubit to collapse into one of the possible basis states, resulting in a classical state that can be represented as a digital one or a digital zero. A representative characteristic of any quantum circuit is the coherence time, during which the readout operation must be performed to avoid losing the information represented by the quantum state.

A known way of performing a readout on a qubit involves using a readout resonator. The qubit is weakly coupled to an adjacent readout resonator, and the energy within the qubit causes, a small shift in the scattering parameters of the combined system consisting of the qubit and the readout resonator. This shift can be detected by transmission of a so-called readout signal, which is a microwave pulse on or close to, e.g. within full-width at half maximum, resonance with the readout resonator.

Assuming that the qubit is a transmon, the interaction between the state of the qubit and the readout signal injected into the readout resonator causes an observable effect in the amplitude and phase of the transmitted signal. This effect is indicative of the state observed in the readout operation. From the readout resonator there are further signal paths that eventually transfer the obtained state out of the cryogenically cooled environment where the quantum processing unit resides.

The readout resonator must be located close to the qubit, the state of which is to be read. Building the signal paths between the readout resonator in the cryogenically cooled environment and the processing electronics in the surrounding room temperature environment is non-trivial, as it requires transmission lines operable at gigahertz frequencies with proper filtering and thermal anchoring to cold bodies in the cryostat. Frequency multiplexing may be utilized to share a common transmission line among about ten readout resonators in practice, the limit being related to readout speed and available bandwidth. Slower readout would allow more channels to be frequency-multiplexed if the hardware and software support it, but slower readout is against the overall goal of taking the best advantage of the limited coherence times of the qubits. In a system where the quantum processing unit comprises only a small number of qubits, these are not big problems. However, with the number of qubits in the quantum processing unit increasing it has been found that the physical space requirements of known readout systems as well as the conducted heat and cost related to a large quantity of wiring may become prohibitively large.

### SUMMARY

The scope of protection sought for various embodiments of the invention is set out by the independent claims. The embodiments, examples and features, if any, described in this specification that do not fall under the scope of the independent claims are to be interpreted as examples useful for understanding various embodiments of the invention.

It is an objective to overcome at least some of the problems identified above related to routing input signals fed to a transmission line to a plurality of outputs arranged to the transmission line.

According to a first aspect there is provided circuitry for routing input signals, comprising:
a transmission line for receiving an input signal;
at least one control line for carrying a control current; and
switching circuitries each of which comprises: a resonator configured to couple to the transmission line based on at least one of an inductive coupling and a capacitive coupling, and provide an output, and a superconducting element comprising a quantum device configured to couple to the resonator based on at least one of an inductive coupling and a capacitive coupling;
wherein the quantum devices of the switching circuitries comprise resonance frequencies that have different periodicities in response to levels of the control current for selectively controlling propagation of the input signal to outputs of resonators of the switching circuitries.

According to a second aspect there is provided a quantum computing system comprising comprising the circuitry according to an aspect.

According to a third aspect there is provided a method for routing input signals by the circuitry according to an aspect.

At least some aspects facilitate a space-efficient construction for routing input signals.

At least some aspects facilitate efficient readout for large-scale quantum computing systems.

### DESCRIPTION OF THE DRAWINGS

Other features and advantages of the invention will become apparent from the following description of a non-limiting example embodiment, with reference to the appended drawings, in which:

FIG. 1 illustrates a schematic example of a circuit for a quantum processing unit in accordance with at least some embodiments;

FIG. 2 illustrates a schematic example of a quantum computing system in accordance with at least some embodiments;

FIG. 3 illustrates a schematic example of a circuit for switching input signals in accordance with at least some embodiments;

FIG. 4 illustrates an example of a method in accordance with at least some embodiments; and

FIG. 5 illustrates an example of a control current for routing input signals in accordance with at least some embodiments.

### DETAILED DESCRIPTION

In the following description, reference is made to the accompanying drawings, which form part of the disclosure, and in which are shown, by way of illustration, specific aspects in which the present disclosure may be placed. It is understood that other aspects may be utilized, and structural or logical changes may be made without departing from the scope of the present disclosure. The following detailed description, therefore, is not to be taken in a limiting sense, as the scope of the present disclosure is defined be the appended claims.

For instance, it is understood that a disclosure in connection with a described method may also hold true for a corresponding device or system configured to perform the method and vice versa. For example, if a specific method step is described, a corresponding device may include a unit to perform the described method step, even if such unit is not explicitly described or illustrated in the figures. On the other hand, for example, if a specific apparatus is described based on functional units, a corresponding method may include a step performing the described functionality, even if such step is not explicitly described or illustrated in the figures. Further, it is understood that the features of the various example aspects described herein may be combined with each other, unless specifically noted otherwise.

The following embodiments are exemplary. Although the specification may refer to “an”, “one”, or “some” embodiment(s) in several locations, this does not necessarily mean that each such reference is to the same embodiment(s), or that the feature only applies to a single embodiment. Single features of different embodiments may also be combined to provide other embodiments.

As used herein, “at least one of the following:” and “at least one of” and similar wording, where the list of two or more elements are joined by “and” or “or”, mean at least any one of the elements, or at least any two or more of the elements, or at least all the elements.

FIG. 1 illustrates a schematic example of a quantum processing unit 100. The quantum processing unit comprises a probe line 101, i.e. a common probe line or a common transmission, where one, two or more other probe lines 102, 103, 104, i.e. sub-probe lines, are connected to. The quantum processing unit comprises quantum devices, e.g. quantum bits or qubits, 114, 116, 118, 124, 126, 128, 134, 136, 138, connected to the sub-probe lines. Accordingly, readout of states of the quantum devices is performed via the common probe line. The sub-probe lines 102, 103, 104 are connected to the common probe line by a circuitry for routing input signals, i.e. a routing circuitry. The routing circuitry comprises switching circuitries 109a, 109b, 109c that are configured to selectively switch an input signal from the probe line 101 to an associated sub-probe line 102, 103, 104 for readout of quantum devices connected to at least one selected sub-probe line without readout from one or more non-selected sub-probe lines. The input signals are routed by the routing circuitry based on a configuration of the switching circuitries which determines whether propagation of the input signal is enabled or disabled by a given switching circuitry 109a, 109b, 109c. Each of the switching circuitries may be coupled to a control line 111 for receiving a control current. Accordingly, it should be noted that there is one control line per switching circuitry or a group of circuitries. In this way there is one control line for controlling each switching circuitry or the group of switching circuitries. Therefore, a total number of control lines is determined by the number of switching circuitries or groups of switching circuitries that are associated with each control line. In an example a single control line may be coupled to ten switching circuitries. The control current provides control over resonance frequencies of the switching circuitries, whereby the switching circuitries may be selectively detuned away from the frequency of the input signal for disabling propagation of the input signal or tuned to the frequency of the input signal for enabling propagation of the input signal from the probe line 101 to the sub-probe lines through the switching circuities. The input signal may be an electrical signal comprising a waveform, for example a microwave signal. The electrical signal may be generated by a signal source that is connected to an input terminal 108 of the common probe line. It should be noted that each sub-probe line may be connected to one or more qubits, whereby the switching circuitries provide control over the number of sub-probe lines that receive the input signal from the common probe line 101 at a given time. In this way, the number of quantum devices readout at the given time may be limited to the number of quantum devices coupled to the selected at least one sub-probe line. Therefore, efficient readout for large-scale quantum computing systems is facilitated. For example, only one of the switching circuitries may be enabled to propagate an input signal from the probe line 101 to an associated sub-probe line 102, 103, 104 at a time, whereby control of the routing circuitry to enable, or disable, the switching circuitries provides selecting sub-probe lines for readout. In this way, the number of quantum devices for readout may be limited to the number of quantum devices, e.g. one to ten quantum devices, coupled to the selected sub-probe line(s). It should be noted that since the readout of the quantum devices is performed via the common probe line, readout can be performed using a common chain of readout electronics connected to the common probe line. This facilitates space-efficient construction for quantum computing systems, where the number of quantum devices and the number of sub-probe lines is large.

It should be noted that the quantum devices 114, 116, 118, 124, 126, 128, 134, 136, 138 coupled to a sub-probe line may be frequency multiplexed for the readout. In this way more than one, e.g. up to ten, quantum devices may be readout simultaneously. The states of the quantum devices may be determined at a frequency band between 5.5 GHz 6.5 GHz frequency band. Therefore, selectively coupling the sub-probe lines provides time division multiplexing of the sub-probe lines for the readout of the frequency multiplexed quantum devices of different sub-probe lines.

An example implementation of the quantum processing unit 100 comprises 10 sub-probe lines each of which is connected to 10 quantum devices, or qubits, whereby a total number of quantum devices becomes 100. Therefore, in the example implementation, 10% of the quantum devices can be readout simultaneously, whereby all the quantum devices may be readout in 2.2 μs<<T1, where T1 is the relaxation time of the quantum devices.

In an example, the common probe line 101 may comprise an input terminal, or input port, 108 at one end of the common probe line and an output terminal, or output port, 110 at another end of the common probe line. An input signal chain may be connected to the input port and used for feeding an input signal, e.g. a microwave signal, to the common probe line and to the switching circuitries. The input signal may be obtained from a signal source. It should be noted that it is viable to implement the input port and the output port of the common probe line using a single port.

In an example, an output signal chain may be connected to one or more output ports of the circuitries for reading corresponding output signals. Since the readout of the quantum devices is performed via the common probe line, the readout can be performed using a common input signal chain.

In an example in accordance with at least some embodiments, the quantum devices, or qubits, comprise qubits such as superconducting qubits or spin-based qubits. Examples of the superconducting qubits comprise at least one of the following: a superconducting charge qubit; or a superconducting flux qubit; or a superconducting phase qubit; or a unimon qubit. The superconducting qubits may be implemented by Josephson junctions. Unimon qubit may comprise a coplanar waveguide, intercepted by at least one Josephson junction, and having a length between its two ends. Spin-based qubits have states that may be defined by spins of charge carriers (electrons and electron holes).

In an example, at a readout operation of quantum devices, one or more of the quantum devices 114, 116, 118 that are connected to a selected sub-probe line are excited. Excitation of a quantum device causes an electromagnetic waveform to an associated readout resonator of the quantum device. The excitation of the quantum device changes the effective resonance frequency of the associated readout resonator. Hence, an electromagnetic waveform close to the resonant frequency of the readout resonator is reflected with a different amplitude and/or phase depending on the state of the quantum device. It should be noted that after the electromagnetic waveform has been reflected, the quantum device may remain excited. Therefore, the waveform has an electric field and a magnetic field that can be coupled to the sub-probe line based on capacitive coupling and/or inductive coupling. Each of the resonators of the quantum devices may have a different resonant frequency, such that frequencies of a readout signal, or a probe signal, read from the common probe line may determine which quantum devices are actually read. Accordingly, the readout signal comprises waveforms of the determined quantum devices at a readout band. Therefore, the readout band comprises multiplexed resonator frequencies that are dispersively coupled to the quantum devices. Phase of the readout signal may be used for detecting states of qubits from the readout signal. It should be noted that depending on implementation, the probe line may be measured in transmission and/or in reflection of the probe signal for reading the states of the quantum devices.

In an example, components of the quantum processing unit, such as quantum devices 114, 116, 118, 124, 126, 128, 134, 136, 138, resonators, common probe line 101, sub-probe lines 102, 103, 14 and switching circuitries 109a, 109b, 109c, can be made of superconductor materials. However, this is not an essential requirement, and other kinds of quantum technologies could be used for a quantum processing unit described herein. A superconductor material means here a material that can be made superconductive by cooling it to a sufficiently low temperature. An example of such materials is aluminium, but also other superconductor materials like molybdenum, niobium, tin, tantalum, or lead can be used. For operation, a superconductive quantum processing unit is cooled to a very low temperature, which can be some kelvins (K), or well under one kelvin, or in the order of some tens of millikelvins.

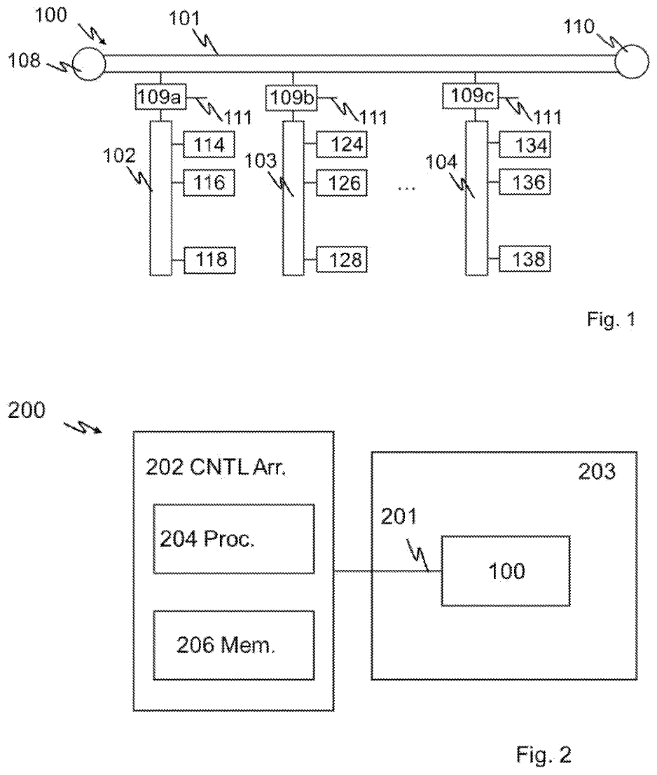

FIG. 2 illustrates a schematic example of a quantum computing system in accordance with at least some embodiments. The quantum computing system 200 comprises a quantum processing unit 100 in accordance to described with FIG. 1. In an example, the quantum processing unit comprises a common probe line 101; sub-probe lines 102, 103, 104 connected to the common probe line 101; and quantum devices 114, 116, 118, 124, 126, 128, 134, 136, 138 connected to the sub-probe lines 102, 103, 104, wherein the sub-probe lines 102, 103, 104 are connected to the common probe line by circuitries for switching input signals, i.e. switching circuitries, and each of the switching circuitries is configured to selectively enable or disable propagation of an input signal to an associated sub-probe line 102, 103, 104 from the common probe line for readout of quantum devices 114, 116, 118. In an example, the quantum processing unit may be located in a cryogenically cooled environment 203.

In an example in an accordance with at least some embodiments, the quantum computing system 200 further comprises a control arrangement 202 operatively connected to the quantum processing unit 100 and the control arrangement is configured to cause one or more functionalities according to an example. It should be noted that the control arrangement may be operatively connected to at least one of the following elements of the quantum processing unit: common probe line 101, control line 111, switching circuitries 109a, 109b, 109c and quantum devices 114, 116, 118, 124, 126, 128, 134, 136, 138. In this way the control arrangement may feed one or more input signals to the quantum processing unit and read one or more output signals from the quantum processing unit. Connections 201 between the control arrangement and the quantum processing unit may be implemented by electrical connections. The connections may provide feeding one or more input signals to the quantum processing unit and reading one or more output signals from the quantum processing unit. In this way the control arrangement may provide at least one of the following: feeding a control current to a control line; coupling control of sub-probe lines; input of coupling control signal; or de-coupling control of sub-probe lines; or readout control; or qubit control; or probe signal input; or reading readout signal.

In an example in an accordance with at least some embodiments, the control arrangement may be operatively connected to the quantum processing unit 100 and the control arrangement is configured to cause selecting at least one of the sub-probe lines 102, 103, 104 and coupling the selected at least one sub-probe line 102 to the common probe line 101 for readout of quantum devices 114, 116, 118 connected to the selected at least one sub-probe line 102.

In an example, the control arrangement 202 comprises at least one processor 204. The at least one processor 204 may include, for example, one or more various processing devices such as a coprocessor, a microprocessor, a control unit, a Digital Signal Processor (DSP), processing circuitry with or without an accompanying DSP, or various other devices including integrated circuits such as, for example, an Application Specific Integrated Circuit (ASIC), a Field Programmable Gate Array (FPGA), a microprocessor unit (MCU), a hardware accelerator, a special-purpose computer chip, or the like.

In an example, the control arrangement 202 comprises at least one memory 206. The memory 206 may be configured to store, for example, one or more of control signal(s), probe signal(s), tuning signal(s), computer program code, computer program instructions and computer programs. Execution of the computer program code, computer program instructions and computer programs may cause at least one of the following for execution of one or more functionalities described herein: selecting sub-probe line(s); or coupling the selected sub-probe line(s); or de-coupling non-selected sub-probe line(s); or reading readout signals; or determining states of one or more quantum devices; or determining an order for selecting sub-probe lines for readout; or changing selected sub-probe line(s).

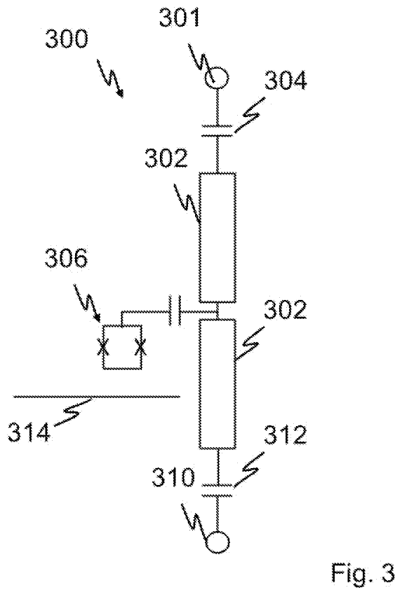

FIG. 3 illustrates a schematic example of a circuitry for switching input signals in accordance with at least some embodiments. The circuitry 300, or switching circuitry, may be used for the switching circuitries 109a, 109b, 109c for a routing circuitry described with FIG. 1. The switching circuitry is configured to selectively control propagation of an input signal from a transmission line to an output 310 of the circuitry. The switching circuitry comprises a resonator 302, an input coupler element 304 for coupling the input signal to the resonator from an input of the switching circuitry 301 and a superconducting element 306 comprising a quantum device configured to couple with the resonator. The input coupler element may be configured to couple to the transmission line based on at least one of an inductive coupling and a capacitive coupling. The superconducting element comprising a quantum device may be configured to couple to the resonator 302 based on at least one of an inductive coupling and a capacitive coupling. Coupling of the quantum device with the resonator provides that the resonance frequency of the resonator may be adapted by the quantum device. The output 310 of the switching circuitry may be provided by an output coupler 312. The output coupler element may be configured to couple the resonator to the output based on at least one of an inductive coupling and a capacitive coupling. Examples of the output of the switching circuitry comprise at least one of the following: a transmission line; or a sub-probe line; or a quantum device. The quantum device 306 may be controlled based on a magnetic flux caused by a control current of a control line 314 that is within proximity of the quantum device. The magnetic flux may be controlled at least based on a level of the control current. The control line may be a common control line for a plurality of routing circuitries.

Referring to both FIG. 1 and FIG. 3, in an example in accordance with at least some embodiments, there is provided a circuitry for routing signals. The circuitry comprises a transmission line 101 for receiving an input signal, at least one control line 314 for carrying a control current and switching circuitries 300. Each of the switching circuitries comprises a resonator 302 configured to couple to the transmission line 101 based on at least one of an inductive coupling and a capacitive coupling, and provide an output 310. Each of the switching circuitries further comprises a superconducting element 306 comprising a quantum device configured to couple to the resonator 302 based on at least one of an inductive coupling and a capacitive coupling. The quantum devices, for example SQUIDs, of the switching circuitries 300 comprise resonance frequencies that have different periodicities in response to levels of the control current for selectively controlling propagation of the input signal to outputs 310 of resonators of the switching circuitries.

In an example, the propagation of the input signal to the outputs is controlled based on controlling the quantum device to be off resonance with the resonator of the switching circuitry for enabling the propagation of the input signal.

In an example, the propagation of the input signal to the outputs is controlled based on controlling the quantum device to be on resonance with the resonator of the switching circuitry for disabling, or at least suppressing, the propagation of the input signal.

In an example in accordance with at least some embodiments, the quantum device is a superconducting quantum interference device, SQUID. The SQUID is a sensitive magnetometer capable of measuring magnetic fields based on superconducting loops.

In an example in accordance with at least some embodiments, the SQUID comprises at least one of the following: a qubit; or Josephson Junctions connected to couplers.

In an example in accordance with at least some embodiments, the quantum device is controlled by a control current from a control line 314. A level of the control current may be adjusted to control a resonance frequency of the resonator 302. The level of the control current may control a frequency at which the quantum device is coupled to an associated resonator, thus the level of the control current controls a frequency of the quantum device. Accordingly, at least one level of the control current may be caused to bring the quantum device on resonance with the resonator and at last one other level of the control current may be caused to bring the quantum device off resonance with the resonator. When the quantum device on resonance with the resonator, propagation of an input signal coupled to the resonator to output of the resonator is disabled, or at least suppressed. When the quantum device off resonance with the resonator, propagation of an input signal coupled to the resonator to output of the resonator is enabled.

It should be noted that a periodicity, in response to a level of the control current, of a resonance frequency of a SQUID of the switching circuit 300 may be determined to be different than periodicities of resonance frequencies of SQUIDs of one or more other switching circuitries that are coupled to the same control line 314. In this way effectively, each level of the control current may enable only one of the switching circuitries coupled to the same control line 314 to propagate an input signal from the input of the switching circuitry 301 to the output 310. Accordingly, when at least one level of the control current causes the quantum device, e.g. a SQUID, of the switching circuitry to be off resonance with the resonator 302, the input signal may propagate to the output. However, at another level of the control current the quantum device, e.g. a SQUID, of the switching circuitry is caused to be on resonance with the resonator 302, whereby propagation of the input signal to output may be disabled or at least suppressed. However, at the another level of the control current, another switching circuitry that is coupled to the same control line may have a SQUID that is controlled by another level of the control current to be off resonance with its associated resonator, which enables propagation of an input signal by that another switching circuitry.

Periodicities, in response to levels of the control current, of the switching circuitries that are coupled to the same control line, can be designed to be different from one another based on adapting characteristics of the switching circuitries that influence their resonance frequencies. Examples of the characteristics that influence resonance frequencies of switching circuitries, where quantum devices are SQUIDS, comprise at least:

### Geometric Variations:

Loop Size: The physical size and shape of the superconducting loop in each SQUID can affect its inductance and consequently its resonant frequency. Adjusting the loop dimensions (area and perimeter) can provide a range of inductive values, leading to different periodicities.
Line Width: The width of the superconducting lines forming the SQUID can also alter its characteristics, influencing both inductance and capacitance.

### Josephson Junction Characteristics:

Critical Current (Ic): The critical current of the Josephson junctions in the SQUID largely determines the magnetic flux sensitivity. Variation in the critical current between different SQUIDs can be achieved by changing the junction area or the barrier characteristics.
Junction Capacitance (C): Variations in the capacitance of the Josephson junctions can affect the dynamics of the SQUID, including its resonance behavior. This can be controlled by modifying the junction's physical dimensions or material properties.

### Material Properties:

Type of Superconductor: Different superconducting materials have different critical temperatures, penetration depths, and coherence lengths, which can influence the overall behavior of the SQUID.
Substrate Material: The choice of substrate can affect the thermal and electromagnetic environment of the SQUIDs, potentially influencing their performance and frequency characteristics.

### Magnetic Environment:

Shielding: Adequate shielding is crucial to prevent cross-talk and magnetic interference between adjacent SQUIDs on the same control line. The effectiveness of shielding can also influence the resonant frequencies by altering the effective magnetic flux threading the SQUID loops.
Layout: The physical layout and proximity of SQUIDs to one another can result in magnetic coupling, which might necessitate careful design to ensure distinct periodicities.

### Coupling Design:

Control Line Coupling: The way each SQUID is coupled to the control line can influence its response. Different coupling mechanisms (e.g., capacitive vs. inductive) and strengths can be used to modulate the resonant frequency periodicities.
Isolation Techniques: Techniques such as the use of isolation amplifiers or buffers can help in managing how the signal from the control line affects each SQUID, ensuring that the periodicity remains distinct.

In an example, a distance from the control line 314 to the quantum device of switching circuitry may be determined based on a sensitivity of the quantum device to the control current coupled from the control line to the quantum device. In an example, the quantum device is a SQUID and a sensitivity of the squid to the control current can be tuned by a size of the area of the SQUID. It should be noted that, that the control line 314 may be configured to control more than one switching circuitry or to control a group of switching circuitries, whereby a distance of the control line and each switching circuitry may be the determined based on a sensitivity of a quantum device of each switching circuitry.

In an example in accordance with at least some embodiments, there is provided a quantum computing system comprising the circuitry for routing signals. The quantum computing system may be in accordance to described with FIG. 2.

In an example, when the quantum device is on resonance with the resonator 302, resonance frequency, fᵣ, of the resonator is shifted which causes suppression, e.g. in the order of 10s of dB, of the input signal coupled to the resonator from the common transmission line. In this way propagation of the input signal may be disabled. When the quantum device is off resonance with the resonator, resonance frequency, fᵣ, of the resonator is shifted significantly less than in the case of the quantum device being on resonance with the resonator, whereby propagation of the input signal coupled to the resonator from the common transmission line to the output is enabled. Propagation of the input signal to the output may be determined based on measurements. The input signal is propagated to the output based on the measurements that show the input signal at fᵣ at the output. Coupling of the input signal to the output may be expressed by coupling strength g such that

abs(f_{qb}−fᵣ)>>g (1),

where g is the coupling strength of the quantum device to the output and f_{qb} is the frequency of the quantum device, fᵣ is the resonance frequency and abs( ) gives an absolute value.

In an example, the quantum device is a superconducting quantum interference device, SQUID. The frequency of the SQUID, fₛ, may be defined based on

fₛ=fᵣ×sqrt(abs(cos(phi))), (2)

where fᵣ is the resonance frequency of the resonator, phi is the magnetic flux penetrating the SQUID loop, sqrt( ) gives a square root and abs( ) gives an absolute value. Accordingly, the frequency of the SQUID, fₛ, is dependent on the magnetic flux caused by a current level of the current line, number of loops of the SQUID, SQUID dimensions, proximity of control line to the SQUID and/number of junctions.

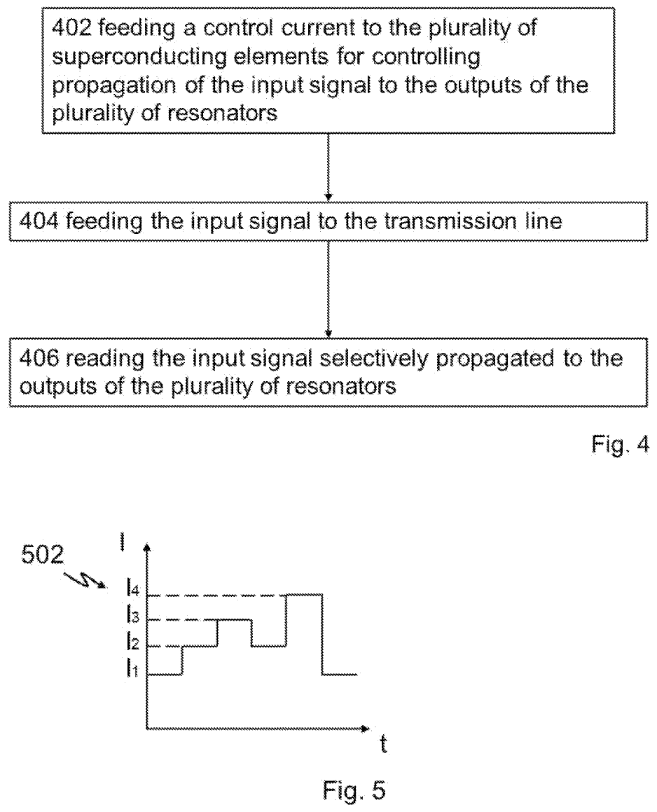

FIG. 4 illustrates an example of a method in accordance with at least some embodiments. The method provides efficient readout of a large-scale quantum computing system. The method may be performed by a quantum computing system described with FIG. 2, for example by the control arrangement 202, that comprises the quantum processing unit described with FIG. 1.

Phase 402 comprises feeding a control current to the plurality of superconducting elements for controlling propagation of the input signal to the outputs of the plurality of resonators. In an example, the propagation of the input signal to the outputs is controlled based on controlling quantum devices of switching circultries to be off resonance with their associated resonators for enabling the propagation of the input signal. In an example, the propagation of the input signal to the outputs is controlled based on controlling quantum devices of switching circuitries to be on resonance with their associated resonators for disabling, or at least suppressing, the propagation of the input signal. Configuration of the switching circuitries, i.e. whether propagation of the input signal is enabled or disabled, determines routing of the input signal through the switching circuitries and which sub-probe line(s) are readout.

Phase 404 comprises feeding the input signal to the transmission line.

Phase 406 comprises reading the input signal selectively propagated to the outputs of the resonators of the switching circuitries. In an example the input signal at an output of a switching circuitry may be read by a sub-probe line connected to the output. In an example, the input signal at an output of a switching circuitry may excite one, two or more qubits.

In an example in accordance with at least some embodiments, phase 402 comprises determining an order at which the sub-probe lines 102, 103, 104 are selected for readout and feeding a control current to superconducting elements for selectively controlling propagation of the input signal to outputs of the plurality of resonators of the switching circuitries. Resonance frequencies of the quantum devices have different periodicities in response to levels of the control current, whereby the control current provides controlling propagation of the input signal to sub-probe lines from outputs of switching circuitries that are controlled by a level of the control current to enable propagation of the inputs signal. In this way the sub-probe lines may be selected in the determined order for readout. In an example, the order for selecting the sub-probe lines for readout may be determined based on an algorithm. For example, some algorithms may need only a part of the qubits of the sub-probe lines to be read at a certain time, and the rest of the qubits may be read at another time. The qubits may be grouped into different probe lines based on their need for readout by the algorithm, such that execution of the algorithm at a certain time may be performed by reading a limited number of sub-probe lines, e.g. just one sub-probe line, of all the sub-probe lines. For example, for a QPU comprising two sub-probe lines, qubits may be grouped based on an algorithm to the two different sub-probe lines. In this way, the qubits needed by the algorithm a certain time may are coupled to one of the two sub-probe lines, whereby readout of qubits from the other sub-probe lines may be omitted at that time, but performed later at another time. In an example, the sub-probe lines may be selected one at a time in their sequential order along the common probe line 101. Accordingly, the sub-probe line that is the closest to an input terminal 108 of the common probe line may be selected first after which the sub-probe line that is the second to closest to the input terminal may be selected. After the last sub-probe line that is closest to an output terminal is selected, the sub-probe line that is the closest to the input terminal may be selected again. In this way each of the probe lines is selected in turn for a uniform readout rate across the sub-probe lines.

In an example in accordance with at least some embodiments, phase 406 comprises changing the selected at least one sub-probe line and reading a readout signal from selected one or more sub-probe lines at a time. In this way after the readout has been performed from the selected at least one sub-probe line, the readout may be performed from other sub-probe lines. Accordingly, each sub-probe line may be selected at a time and coupled to the common probe line for readout of quantum devices connected to the selected sub-probe line.

In an example in accordance with at least some embodiments, phase 402 comprises selecting at least one of the sub-probe lines 102, 103, 104; and enabling propagation of the input signal to the selected at least one sub-probe line 102 from the common probe line 101 for readout of quantum devices 114, 116, 118 connected to the selected at least one sub-probe line 102 without readout from one or more non-selected sub-probe lines 103, 104.

In an example in accordance with at least some embodiments, the quantum computing system 200 may comprise computer program code that when executed by a control arrangement 202 of the quantum computing system causes performance of one or more functionalities according to an example describe herein.

In an example in accordance with at least some embodiments, the quantum computing system 200 may comprise computer program code that when executed by a control arrangement of the quantum computing system causes feeding a control current to the plurality of superconducting elements for controlling propagation of the input signal to the outputs of the plurality of resonators; feeding the input signal to the transmission line; and reading the input signal selectively propagated to the outputs of the plurality of resonators.

It should be noted that the computer program code can be stored in the memory 206 of the quantum computing system. In an example, the propagation of the input signal to the selected at least one sub-probe line 102 may be enabled based on a control current of a routing circuitry configured to couple the selected at least one sub-probe line 102 to the common probe line 101. The propagation of the input signal to non-selected sub-probe lines 103, 104 may be suppressed in a similar manner by control currents of routing circuitries that couple the non-selected sub-probe lines 103, 104 to the common probe line 101.

FIG. 5 illustrates an examples of control current in accordance with at least some embodiments described herein. The control current, I, may be fed to quantum devices of routing circuitries for selectively controlling propagation of an input signal to an output of the routing circuitry. The current may be direct current, DC. The quantum device may have a resonance frequency that has a periodicity. The periodicity may be determined based on a configuration of the quantum device. In an example the quantum device is a SQUID and the periodicity may be determined based by a magnetic flux caused by a current level of a current line, number of loops of the SQUID, SQUID dimensions, proximity of control line to the SQUID and/number of junctions. FIG. 5 illustrates four levels 502 of the control current 11, 12, 13 and 14. In an example each level of the control current may enable at least one routing circuitry to propagate an input signal from a transmission line to an output.

Any range or device value given herein may be extended or altered without losing the effect sought. Also, any embodiment may be combined with another embodiment unless explicitly disallowed.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item may refer to one or more of those items.

Aspects of any of the embodiments described above may be combined with aspects of any of the other embodiments described to form further embodiments without losing the effect sought.

The term ‘comprising’ is used herein to mean including the method, blocks or elements identified, but that such blocks or elements do not comprise an exclusive list and a method or apparatus may contain additional blocks or elements.

It will be understood that the above description is given by way of example only and that various modifications may be made by those skilled in the art. The above specification, examples and data provide a complete description of the structure and use of exemplary embodiments. Although various embodiments have been described above with a certain degree of particularity, or with reference to one or more individual embodiments, those skilled in the art could make numerous alterations to the disclosed embodiments without departing from the spirit or scope of this specification.

### LIST OF REFERENCE SIGNS

Quantum processing unit 100
Common probe line 101
Sub-probe line 102, 103, 104
Probe line terminals 108, 110
Switching circuitry 109a, 109b, 109c
Control line 111
Quantum devices 114, 116, 118, 124, 126, 128, 134, 136, 138
Quantum computing system 200
Control Arrangement 202
Processor 204
Memory 206
Connections 201
Cryogenically cooled environment 203
Switching circuitry 300
Input of routing circuitry 301
Resonator 302
Input coupler element 304
Superconducting element 306
Output of routing circuitry 310
Output coupler element 312
Control line 314
Phases of method of FIG. 4 402, 404, 406
Levels of control current 502

1. A circuitry for routing input signals, comprising:
a transmission line for receiving an input signal;
at least one control line for carrying a control current; and
switching circuitries each of which comprises:
a resonator configured to couple to the transmission line based on at least one of an inductive coupling and a capacitive coupling, and provide an output, and
a superconducting element comprising a quantum device configured to couple to the resonator based on at least one of an inductive coupling and a capacitive coupling;
wherein the quantum devices of the switching circuitries comprise resonance frequencies that have different periodicities in response to levels of the control current for selectively controlling propagation of the input signal to outputs of resonators of the switching circuitries.

2. The circuitry of claim 1, wherein the quantum devices are superconducting quantum interference devices, SQUIDs.

3. The circuitry of claim 2, wherein the SQUIDs comprise at least one of the following: qubits; or Josephson Junctions connected to couplers.

4. The circuitry of claim 3, wherein the input signal is a microwave signal.

5. A quantum computing system comprising the circuitry of claim 4.

6. The quantum computing system of claim 5, further comprising a control device operatively coupled to the transmission line and two or more qubits connected to outputs of the resonators and the control device is configured to:
excite the two or more qubits based on the outputs of the resonators;
read a readout signal from the excited two or more qubits;
determine a state of at least one qubit based on the readout signal.

7. A method for routing input signals by the circuitry of claim 4, comprising:
feeding a control current to the superconducting elements for controlling propagation of the input signal to the outputs of the resonators;
feeding the input signal to the transmission line;
reading the input signal selectively propagated to the outputs of the resonators.

8. The method of claim 7, comprising:
determining an order at which the sub-probe lines are selected for readout and feeding a control current to superconducting elements for selectively controlling propagation of the input signal to outputs of the resonators of the switching circuitries.

9. The method of claim 8, comprising:
changing the selected at least one sub-probe line;
and reading a readout signal from selected one or more sub-probe lines at a time.

10. The method of claim 9, comprising:
selecting at least one of the sub-probe lines and enabling propagation of the input signal to the selected at least one sub-probe line from a common probe line for readout of quantum devices connected to the selected at least one sub-probe line without readout from one or more non-selected sub-probe lines.
